(19) United States
(12) Patent Application Publication
(10) Pub. No.: US 2025/0098327 A1
(43) Pub. Date: Mar. 20, 2025

(54) INTEGRATED CIRCUIT BASED ON GRID AND METHOD OF DESIGNING THE SAME

(71) Applicant: SAMSUNG ELECTRONICS CO., LTD., Suwon-si (KR)

(72) Inventors: Hankyung Kim, Suwon-si (KR); Hana Kim, Suwon-si (KR); Seungkwon Lee, Suwon-si (KR); Jiye Lee, Suwon-si (KR); Yeonil Jung, Suwon-si (KR)

(21) Appl. No.: 18/810,817

(22) Filed: Aug. 21, 2024

(30) Foreign Application Priority Data
Sep. 19, 2023 (KR) 10-2023-0125011
Feb. 6, 2024 (KR) 10-2024-0018413

(51) Int. Cl. H01L 27/02; H01L 29/06; H01L 29/423; H01L 29/775; H01L 29/78; H01L 29/786

(52) U.S. Cl. CPC H10D 89/10; H10D 30/43; H10D 30/6735; H10D 30/6757; H10D 62/121; H10D 84/83

(57) ABSTRACT

An integrated circuit includes devices arranged in a grid configuration and a first metal layer on the devices, wherein the grid includes first grid lines arranged in a first direction based on a first pitch and extending in a second direction, and second grid lines arranged in the second direction based on a second pitch and extending in the first direction. At least one of the plurality of devices includes gate lines extending in the second direction and having the first pitch, and the first metal layer includes first metal lines extending in the first direction and having the second pitch.

### CROSS-REFERENCE TO RELATED APPLICATIONS

This application claims priority to Korean Patent Application No. 10-2023-0125011, filed in the Korean Intellectual Property Office on Sep. 19, 2023, and Korean Patent Application No. 10-2024-0018413, filed in the Korean Intellectual Property Office on Feb. 6, 2024, the disclosures of which are incorporated herein by reference in their entireties.

### BACKGROUND

An integrated circuit may include various intellectual properties (IPs) such as analog blocks, digital blocks, and mixed signal blocks. In this case, blocks, cells, or devices included in such various IPs may have different sizes depending on the functions and characteristics thereof. Because buffer spaces are required between such blocks, cells, devices, and/or IPs, integrated circuit manufacturing processes become more difficult, and there is a limit in reducing the chip size of integrated circuits.

### SUMMARY

In general, in some aspects, the present disclosure is directed toward an integrated circuit designed based on a grid and a method of designing the integrated circuit.

According to some implementations, the present disclosure is directed to an integrated circuit including a plurality of devices arranged in a grid configuration and a first metal layer on the plurality of devices. The grid includes a plurality of first grid lines arranged in a first direction based on a first pitch and extending in a second direction crossing the first direction, and a plurality of second grid lines arranged in the second direction based on a second pitch and extending in the first direction. At least one of the plurality of devices includes a plurality of gate lines extending in the second direction and having the first pitch, and the first metal layer includes a plurality of first metal lines extending in the first direction and having the second pitch.

According to some implementations, the present disclosure is directed to an integrated circuit including a plurality of cells arranged in a grid configuration having a first pitch. The grid includes a plurality of grid lines arranged in a first direction based on the first pitch and extending in a second direction crossing the first direction. The plurality of cells includes a first cell including first gate lines respectively overlapping first grid lines among the plurality of grid lines and each extending in the second direction, and a second cell including at least one second gate line overlapping second grid lines among the plurality of grid lines and extending in the second direction. The first pitch corresponds to a pitch of the first gate lines, and a first length of each of the first gate lines in the first direction is less than a second length of the at least one second gate line in the first direction.

According to some implementations, the present disclosure is directed to an integrated circuit including a plurality of blocks arranged in a grid configuration having a first pitch and a first metal layer on the plurality of blocks. The first metal layer includes a plurality of first metal lines each extending in a first direction and arranged apart from each other in a second direction crossing the first direction. The first pitch corresponds to a pitch of the plurality of first metal lines. The grid includes a plurality of grid lines extending in the first direction and arranged in the second direction based on the first pitch.

### BRIEF DESCRIPTION OF THE DRAWINGS

Example implementations will be more clearly understood from the following detailed description, taken in conjunction with the accompanying drawings.

FIG. 1 is a layout illustrating an example of integrated circuit according to some implementations.

FIG. 2 is a plan view illustrating an example of an integrated circuit according to some implementations.

FIG. 3A is a cross-sectional view taken along line X1-X1′ of FIG. 2 according to some implementations, and FIG. 3B is a cross-sectional view taken along the line X2-X2′ of FIG. 2 according to some implementations.

FIG. 4 is a plan view illustrating an example of an integrated circuit according to some implementations.

FIG. 5A is a cross-sectional view taken along line X3-X3′ of FIG. 4 according to some implementations, and FIG. 5B is a cross-sectional view taken along the line X4-X4′ of FIG. 4 according to some implementations.

FIG. 6 is a plan view illustrating an example of an integrated circuit according to some implementations.

FIG. 7A is a cross-sectional view taken along line Y1-Y1′ of FIG. 6 according to some implementations, and FIG. 7B is a cross-sectional view taken along line Y2-Y2′ of FIG. 6 according to some implementations.

FIG. 8 is a layout illustrating an example of an integrated circuit according to some implementations.

FIG. 9A is a plan view illustrating an example of an integrated circuit according to some implementations, and FIG. 9B is a cross-sectional view taken along line X5-X5′ of FIG. 9A according to some implementations.

FIG. 10 is a layout illustrating an example of an integrated circuit according to some implementations.

FIG. 11A is a plan view illustrating an example of an integrated circuit according to some implementations, and FIG. 11B is a cross-sectional view taken along line X6-X6′ of FIG. 11A according to some implementations.

FIG. 12 is a layout illustrating an example of an integrated circuit according to some implementations.

FIG. 13A is a plan view illustrating an example of an integrated circuit according to some implementations, and FIG. 13B is a cross-sectional view taken along line X7-X7′ of FIG. 13A according to some implementations.

FIG. 14 is a layout illustrating an example of an integrated circuit according to some implementations.

FIG. 15 is a layout illustrating an example of an integrated circuit according to some implementations.

FIG. 16 is a layout illustrating an example of an integrated circuit according to some implementations.

FIGS. 17A to 17D are views illustrating examples of devices according to some implementations.

FIG. 18 is a flowchart illustrating an example of a method of manufacturing an integrated circuit according to some implementations.

FIG. 19 is a block diagram illustrating an example of a system-on-chip (SoC) according to some implementations.

FIG. 20 is a block diagram illustrating an example of a computing system including memory storing a program according to some implementations.

### DETAILED DESCRIPTION

Hereinafter, example implementations will be described in detail with reference to the accompanying drawings. In the drawings, like reference numerals denote like elements, and repeated descriptions thereof are omitted.

In the present disclosure, an X-axis direction may be referred to as a first horizontal direction or a first direction, a Y-axis direction may be referred to as a second horizontal direction or a second direction, and a Z-axis direction may be referred to as a vertical direction. A plane formed by an X-axis and a Y-axis may be referred to as a horizontal plane, elements arranged in a positive (+) Z-axis direction relative to other elements may be referred to as being located on or above the other elements, and elements arranged in a negative (−) Z-axis direction relative to other elements may be referred to as being located below or under the other elements.

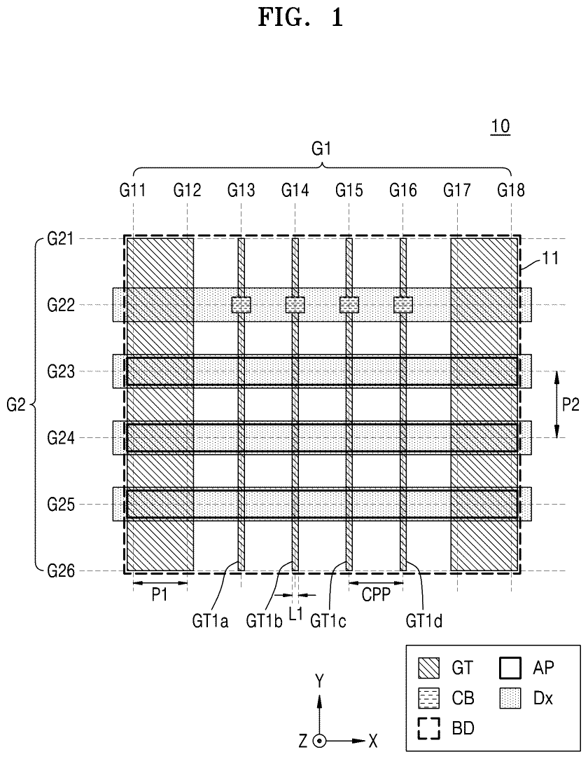

FIG. 1 is a layout illustrating an example of an integrated circuit according to some implementations. In FIG. 1, an integrated circuit 10 may include a first cell 11 and a metal layer Dx. The integrated circuit 10 may be implemented as a semiconductor device. According to some implementations, the first cell 11 and the metal layer Dx may be placed or arranged and routed based on a grid or grid configuration. In this case, the grid may include first grid lines G1 and second grid lines G2. In some implementations, the first cell 11 may be referred to as a first block or a first device. In some implementations, the first cell 11 may correspond to a short channel device. For example, the first cell 11 may include a logic device such as a standard cell or a memory device such as a static random-access memory (SRAM) device.

The first cell 11 may include gate lines GT arranged along the first grid lines G1. In addition, the first cell 11 may further include gate contacts CB arranged along the first and second grid lines G1 and G2. In addition, the first cell 11 may further include active patterns AP arranged along the second grid lines G2. For example, the first cell 11 may be defined by a boundary BD and may correspond to a standard cell or a functional cell. In addition, the metal layer Dx may include a plurality of metal lines Dx routed along the second grid lines G2.

In some implementations, the first grid lines G1 may be referred to as vertical grid lines. For example, the first grid lines G1 may include first grid lines G11 to G18 that are apart from each other in a first direction X and extend in a second direction Y. The first grid lines G11 to G18 may have a first pitch P1. In some implementations, the first pitch P1 may correspond to the pitch of the gate lines GT, that is, a contacted poly pitch (CPP). Accordingly, the first grid lines G11 to G18 may be arranged with the first pitch P1 in the first direction X.

In some implementations, the second grid lines G2 may be referred to as horizontal grid lines. For example, the second grid lines G2 may include second grid lines G21 to G26 each extending in the first direction X and arranged apart from each other in the second direction Y. The second grid lines G21 to G26 may have a second pitch P2. In some implementations, the second pitch P2 may correspond to the pitch of the metal lines Dx. Accordingly, the second grid lines G21 to G26 may be arranged with the second pitch P2 in the second direction Y. For example, the second pitch P2 may be greater than or equal to the first pitch P1. However, the present disclosure is not limited thereto, and the first and second pitches P1 and P2 may vary depending on some implementations.

The gate lines GT may include gate lines GT1a to GT1d arranged along the first grid lines G13 to G16. In this case, the pitch of the gate lines GT1a to GT1d, that is, a CPP, may correspond to the first pitch P1. For example, the gate lines GT1a to GT1d may respectively overlap the first grid lines G13 to G16. For example, the gate lines GT1a to GT1d may be respectively aligned with the first grid lines G13 to G16, and centerlines of the gate lines GT1a to GT1d may respectively correspond to the first grid lines G13 to G16. In some implementations, the length of each of the gate lines GT1a to GT1d in the first direction X may be a first length L1.

The gate contacts CB may be respectively disposed on the gate lines GT1a to GT1d. The gate contacts CB may be arranged along the first grid lines G13 to G16, and the pitch of the gate contacts CB may correspond to the first pitch P1. In addition, the gate contacts CB may be arranged along the second grid line G22. For example, the gate contacts CB may be aligned with the second grid line G22, and centerlines of the gate contacts CB may correspond to the second grid line G22.

The active patterns AP may be arranged along the second grid lines G23 to G25, and the pitch of the active patterns AP may correspond to the second pitch P2. For example, the active patterns AP may be aligned with the second grid lines G23 to G25, and centerlines of the active patterns AP may respectively correspond to the second grid lines G23 to G25. For example, the active patterns AP may be diffusion regions that are doped with a dopant to change electrical characteristics of a substrate material and may form source/drain regions of transistors.

In some implementations, the active patterns AP may correspond to nanosheets, and in this case, the integrated circuit 10 may include multi-bridge channel field effect transistors (MBCFETs). However, the present disclosure is not limited thereto. In some implementations, the active patterns AP may correspond to nanowires, and in this case, the integrated circuit 10 may include gate-all-around field effect transistors (GAAFETs). Furthermore, in some implementations, the active patterns AP may correspond to fin structures or fins, and in this case, the integrated circuit 10 may include fin field effect transistors (FinFETs).

The metal lines Dx may be arranged along the second grid lines G22 to G25, and the pitch of the metal lines Dx may correspond to the second pitch P2. For example, the metal lines Dx may be aligned with the second grid lines G22 to G25, and centerlines of the metal lines Dx may respectively correspond to the second grid lines G22 to G25. For example, the metal lines Dx may be signal routing level lines. For example, the metal lines Dx may be disposed above the first cell 11 in a vertical direction Z. For example, the metal lines Dx may be included in an uppermost metal layer of the integrated circuit 10, but the disclosure is not limited thereto.

The integrated circuit 10 may further include various front wiring layers, such as front via layers and front metal layers, that are disposed above the first cell 11 in the vertical direction Z and are electrically connected to the first cell 11. For example, the front via layers and the front metal layers may be disposed between the first cell 11 and the metal lines Dx. For example, the front via layers and the front metal layers may be disposed above the metal layers Dx in the vertical direction Z. In this case, the front via layers and the front metal layers may be placed and routed along the grid including the first grid lines G1 and the second grid lines G2.

In addition, the integrated circuit 10 may further include various backside wiring layers, such as backside contacts, backside via layers, and backside metal layers, that are disposed below the first cell 11 in the vertical direction Z and are electrically connected to the first cell 11. In this case, the backside contacts, the backside via layers, and the backside metal layers may be placed and routed along the grid including the first grid lines G1 and the second grid lines G2. In addition, the integrated circuit 10 may further include through-electrodes such as through-silicon vias (TSVs). In this case, the through-electrodes may be placed and routed along the grid including the first grid lines G1 and the second grid lines G2.

Furthermore, the integrated circuit 10 may further include another cell, block or device that is adjacent to the first cell 11 in the first direction X, and another cell, block, or device that is adjacent to the first cell 11 in the second direction Y. In this case, the cells, blocks, and/or devices may be placed or arranged along the grid including first grid lines G1 and second grid lines G2. Accordingly, the integrated circuit 10 may reduce unnecessary space between adjacent cells, adjacent blocks, and/or adjacent IPs, and the size of a semiconductor chip including the integrated circuit 10 may be reduced.

As described above, according to some implementations, difficulties in manufacturing processes of the integrated circuit 10 and the chip size of the integrated circuit 10 may be reduced by arranging devices, cells, and blocks based on the grid and routing wiring lines based on the grid. For example, difficulties in manufacturing processes and design verification may be reduced by setting vertical grid lines based on the pitch of the gate lines GT, setting horizontal grid lines based on the pitch of signal routing lines, and arranging patterns, lines, and/or regions of devices based on the vertical grid lines and the horizontal grid lines. In addition, buffer space may be reduced by placing devices, cells, and blocks based on the vertical grid lines and the horizontal grid lines, and the chip size of the integrated circuit 10 may be reduced.

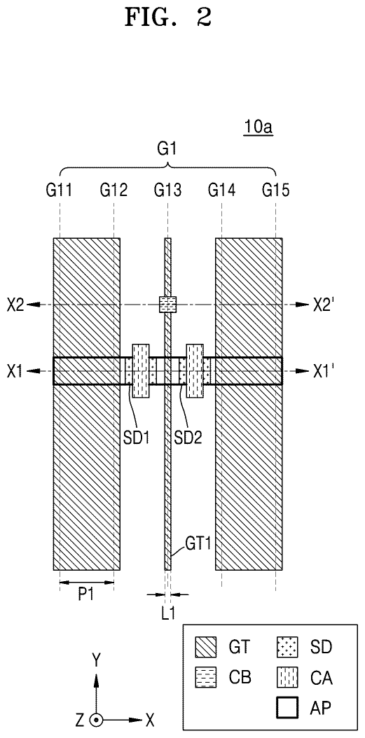

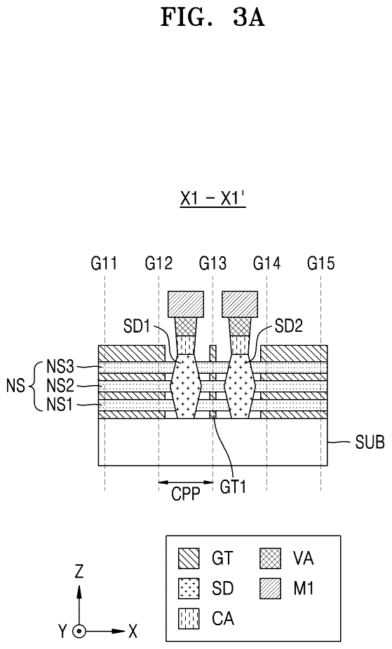

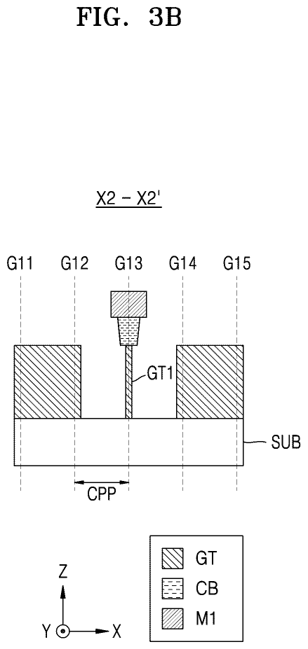

FIG. 2 is a plan view illustrating an example of an integrated circuit according to some implementations. FIG. 3A is a cross-sectional view taken along line X1-X1′ of FIG. 2 according to some implementations, and FIG. 3B is a cross-sectional view taken along line X2-X2′ of FIG. 2 according to some implementations.

In FIGS. 2 to 3B, an integrated circuit 10a may include gate lines GT, an active pattern AP, source/drain regions SD, source/drain contacts CA, and a gate contact CB. The integrated circuit 10a may correspond to an implementation of the integrated circuit 10 described with reference to FIG. 1, and the description given with reference to FIG. 1 may also be applied to the present implementations.

The integrated circuit 10a may further include front via layers and front metal layers that are disposed above the source/drain contacts CA and the gate contact CB and are electrically connected to the source/drain contacts CA and/or the gate contact CB. In addition, the integrated circuit 10a may further include backside contacts, backside via layers, and backside metal layers that are disposed below the active pattern AP, the source/drain regions SD, and the gate lines GT, and are electrically connected to the source/drain regions SD and/or the gate lines GT.

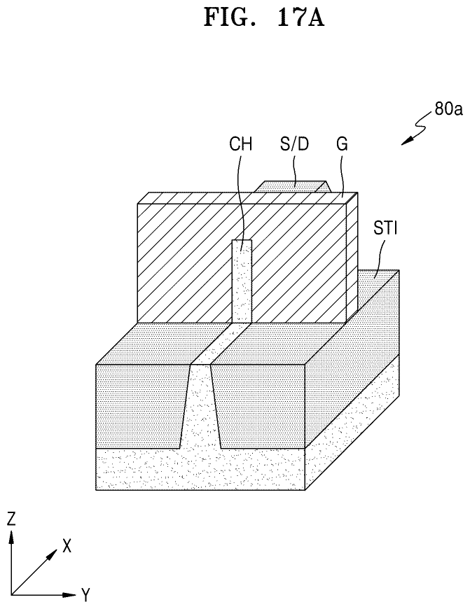

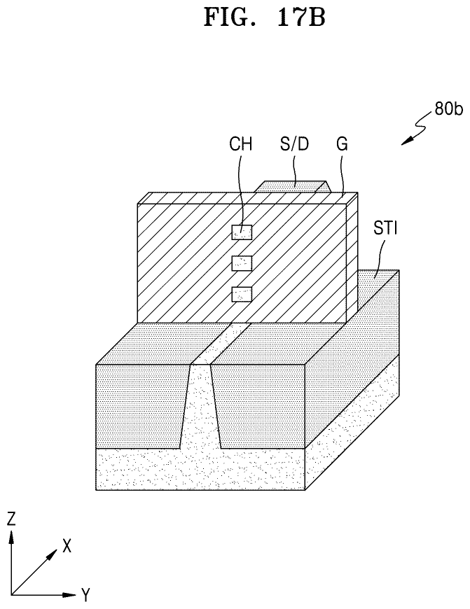

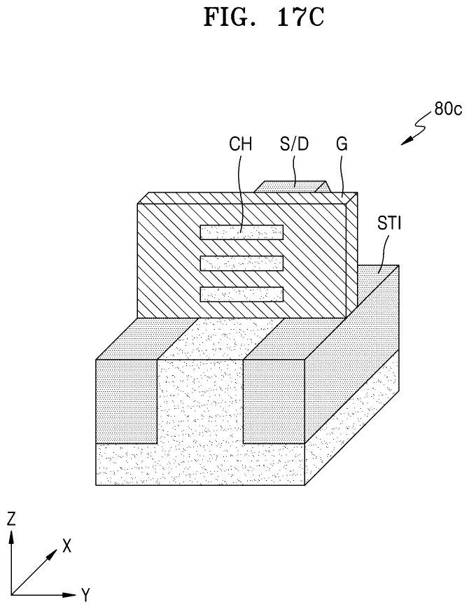

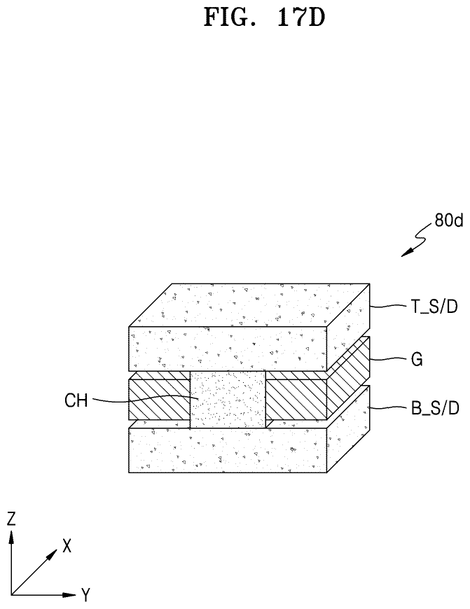

FIGS. 3A and 3B show an example in which nanosheets are formed in an active region. For example, an MBCFET, in which a plurality of nanosheets are stacked in an active region and gate lines surrounds the nanosheets, may be formed. However, integrated circuits of the present disclosure are not limited to the example shown in FIGS. 3A and 3B. For example, a FinFET including a fin and a gate line that are formed in an active region may be formed. In another example, a GAAFET in which nanowires formed in an active region are surrounded by a gate line may be formed. These are described with reference to FIGS. 17A to 17D.

A substrate SUB may include a semiconductor substrate. For example, the semiconductor substrate may include at least one of selected from the group consisting of silicon, a silicon-on-insulator (SOI), silicon-on-sapphire, germanium, silicon-germanium, and gallium-arsenide. An interlayer insulating film may be disposed on an upper side of the substrate SUB. The interlayer insulating film may include an insulating material. For example, the insulating material may include at least one selected from the group consisting of an oxide film, a nitride film, and an oxynitride film.

A gate line GT1 may overlap a first grid line G13 and may extend in a second direction Y. The gate line GT1 may have a first length L1 in a first direction X. The gate contact CB may be disposed on the gate line GT1. The gate contact CB may overlap the first grid line G13. A first metal layer M1 may be disposed on the gate contact CB, and the gate line GT1 may be electrically connected to the first metal layer M1 through the gate contact CB. Therefore, the gate line GT1 may be used as a real gate line. For example, a gate line GT overlapping first grid lines G11 and G12 and a gate line GT overlapping first grid lines G14 and G15 may correspond to dummy gate lines.

The active pattern AP may extend in the first direction X. For example, the active pattern AP may include nanosheets NS. A nanosheet stack or the nanosheets NS extending in the first direction X may be disposed on the upper side of the substrate SUB. The nanosheet stack or the nanosheets NS may include a plurality of nanosheets overlapping each other in a vertical direction Z, for example, first to third nanosheets NS1 to NS3. For example, nanosheets NS disposed on an N-well may be doped with a P-type dopant and may form a P-type transistor. In addition, nanosheets NS disposed on a P-type substrate may be doped with an N-type dopant and may form an N-type transistor. In some implementations, the nanosheets NS may include silicon (Si), germanium (Ge), or SiGe. In some implementations, the nanosheets NS may include InGaAs, InAs, GaSb, InSb, or a combination thereof.

Each of the gate lines GT may cover the nanosheet stack NS and surround each of the first to third nanosheets NS1 to NS3. Accordingly, the first to third nanosheets NS1 to NS3 may have a gate-all-around (GAA) structure. The gate lines GT may be defined as conductive segments including polysilicon and a conductive material, such as at least one metal. Gate insulating films may be disposed between each of the gate lines GT and the first to third nanosheets NS1 to NS3.

The source/drain regions SD may each include an epitaxial region of a semiconductor material, such as silicon (Si), boron (B), phosphorus (P), germanium (Ge), carbon (C), SiGe, and/or SiC. The source/drain regions SD may include a first source/drain region SD1 and a second source/drain region SD2 that are arranged on both sides of the gate line GT1. The source/drain contacts CA may be respectively arranged on the first and second source/drain regions SD1 and SD2. Vias VA may be respectively arranged on the source/drain contacts CA, and the first metal layer M1 may be disposed on the vias VA. The first and second source/drain regions SD1 and SD2 may be electrically connected to the first metal layer M1 through the source/drain contacts CA and the vias VA.

In some implementations, the integrated circuit 10a may include a front wiring layer disposed on a front side of the substrate SUB and a backside wiring layer disposed on a backside of the substrate SUB, and a power distribution network (PDN) may be implemented using the front wiring layer and the backside wiring layer. Accordingly, a portion of signals and/or power applied to the integrated circuit 10a may be transmitted through the front wiring layer, that is, a front side PDN (FSPDN), and the remainder may be transmitted through the backside wiring layer, that is, backside PDN (BSPDN). According to some implementations, routing complexity may be reduced compared to a structure in which wiring is arranged only on a front side of a substrate, and the length of each wiring line or each via may also be reduced, thereby improving the performance of the integrated circuit 10a. In addition, according to some implementations, front wiring layers and backside wiring layers may be routed in a grid configuration, thus, routed along a grid including first and second grid lines G1 and G2 (refer to FIG. 1), thereby reducing difficulties in manufacturing processes and a chip size.

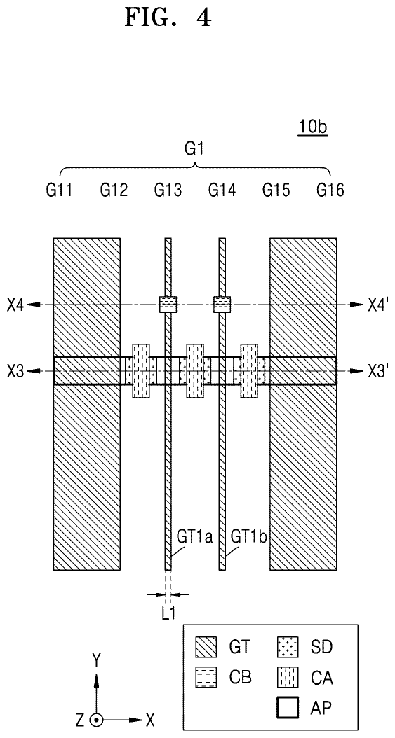

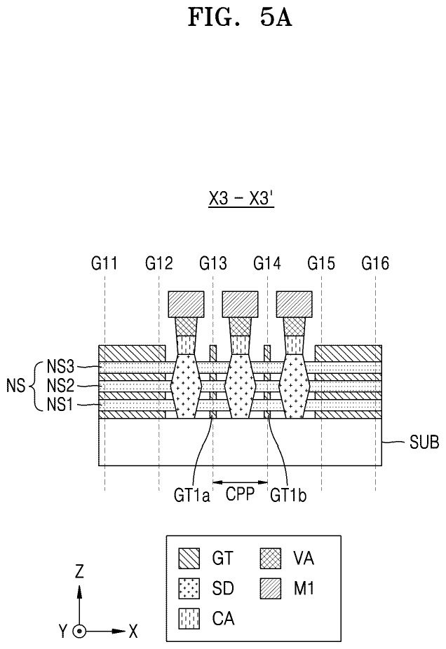

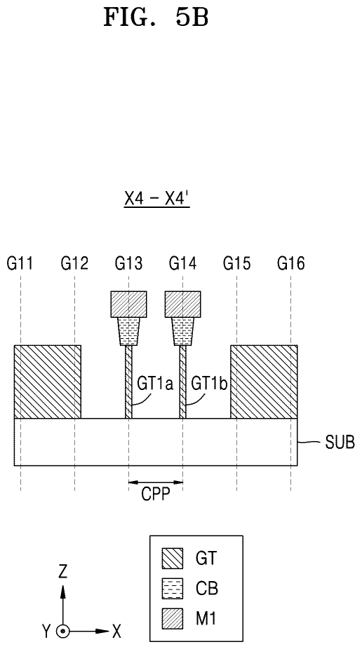

FIG. 4 is a plan view illustrating an example of an integrated circuit according to some implementations. FIG. 5A is a cross-sectional view taken along line X3-X3′ of FIG. 4 according to some implementations, and FIG. 5B is a cross-sectional view taken along line X4-X4′ according to some implementations.

In FIGS. 4, 5A, and 5B, an integrated circuit 10b may correspond to a modification of the integrated circuit 10a shown in FIG. 2. The integrated circuit 10b may include gate lines GT arranged along first grid lines G1 having a first pitch P1. For example, the integrated circuit 10b may include a gate line GT1a overlapping a first grid line G13 and a gate line GT1b overlapping a first grid line G14. Gate contacts CB may be respectively disposed on the gate lines GT1a and GT1b, and the gate lines GT1a and GT1b may be electrically connected to a first metal layer M1 through the gate contacts CB. The length of each of the gate lines GT1a and GT1b in a first direction X may be a first length L1, and the pitch of the gate lines GT1a and GT1b, that is, a CPP, may correspond to the first pitch P1.

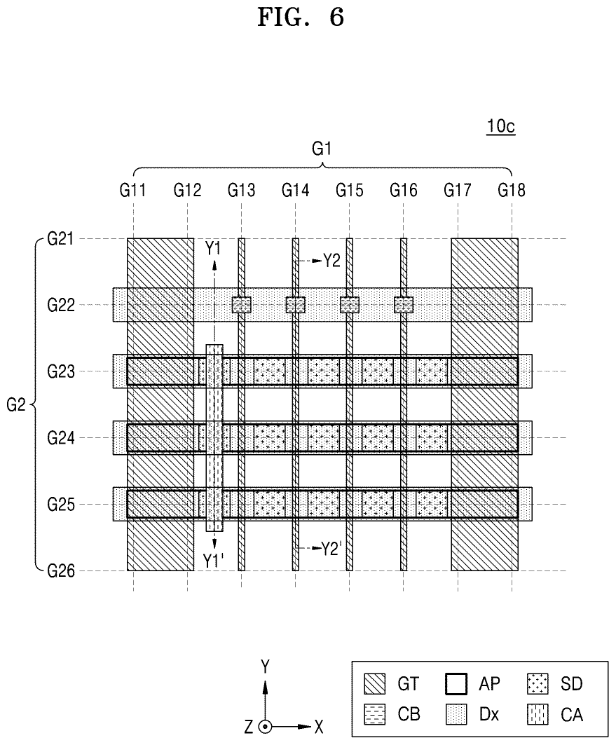

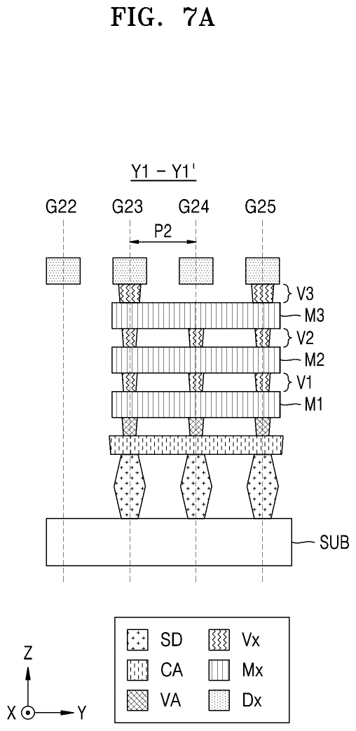

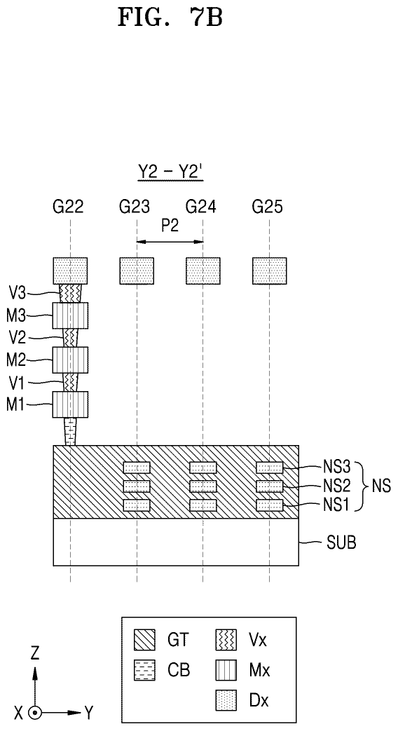

FIG. 6 is a plan view illustrating an example of an integrated circuit according to some implementations. FIG. 7A is a cross-sectional view taken along line Y1-Y1′ of FIG. 6 according to some implementations, and FIG. 7B is a cross-sectional view taken along line Y2-Y2′ of FIG. 6 according to some implementations.

In FIGS. 6, 7A, and 7B, an integrated circuit 10c may include gate lines GT, active patterns AP, source/drain regions SD, source/drain contacts CA, gate contacts CB, and metal lines Dx. The integrated circuit 10c may correspond to a modification of the integrated circuit 10 of FIG. 1, the integrated circuit 10a of FIG. 2, or the integrated circuit 10b of FIG. 4, and the descriptions given with reference to FIGS. 1 to 5B may also be applied to the present implementations.

According to some implementations, the metal lines Dx may be arranged along second grid lines G2 having a second pitch P2, and the pitch of the metal lines Dx may correspond to the second pitch P2. Although only the metal lines Dx are shown in FIG. 6 for case of illustration, the integrated circuit 10c may further include a plurality of metal layers and a plurality of via layers between the metal lines Dx and the source/drain contacts CA or the gate contacts CB. The number of metal layers and the number of via layers may vary.

For example, first to third metal layers M1 to M3, first to third via layers V1 to V3, and vias VA may be disposed between the source/drain contacts CA and the metal lines Dx. The source/drain contacts CA may be electrically connected to the first metal layer M1 through the vias VA. The first metal layer M1 may be electrically connected to the second metal layer M2 through the first via layer V1. The second metal layer M2 may be electrically connected to the third metal layer M3 through the second via layer V2. The third metal layer M3 may be electrically connected to the metal lines Dx through the third via layer V3. However, the present disclosure is not limited thereto, and four or more metal layers and four or more via layers may be disposed below the metal lines Dx. In some implementations, the pitch of at least one of the first to third metal layers M1, M2, and M3 may be determined based on a first pitch P1. In some implementations, the pitch of at least one of the first to third metal layers M1, M2, and M3 may be determined based on a second pitch P2.

In some implementations, the metal lines Dx may be aligned with second grid lines G22 to G25, and centerlines of the metal lines Dx may respectively correspond to the second grid lines G22 to G25. In some implementations, the active patterns AP may be aligned with the second grid lines G23 to G25, and centerlines of the active patterns AP may respectively correspond to the second grid lines G23 to G25. In some implementations, the source/drain regions SD may be aligned with the second grid lines G23 to G25, and centerlines of the source/drain regions SD may respectively correspond to the second grid line G23 to G25.

In some implementations, the gate contacts CB may be aligned with the second grid line G22, and a centerline of each of the gate contacts CB may correspond to the second grid line G22. In some implementations, the vias VA may be aligned with the second grid lines G23 to G25, and centerlines of the vias VA may respectively correspond to the second grid lines G23 to G25. In some implementations, the first to third via layers V1 to V3 may be aligned with the second grid lines G22 to G25, and centerlines of vias of the first to third via layers V1 to V3 may correspond to the second grid lines G22 to G25.

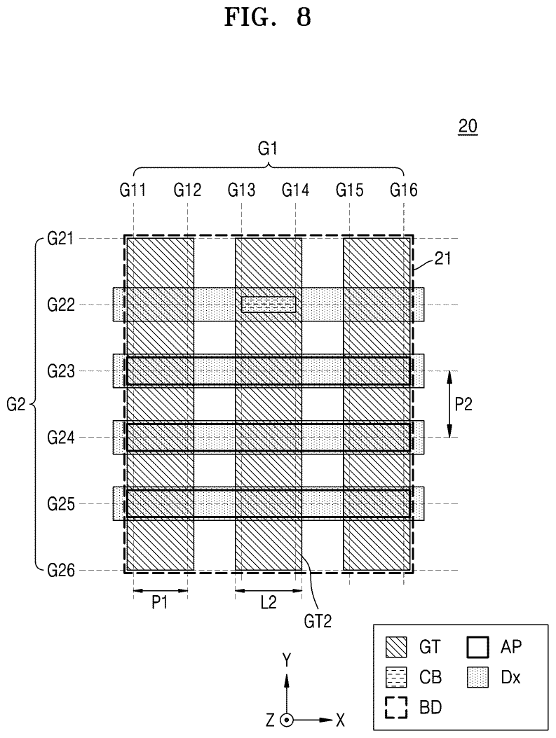

FIG. 8 is a layout illustrating an example of an integrated circuit according to some implementations. In FIG. 8, an integrated circuit 20 may include a second cell 21 and a metal layer Dx. According to some implementations, the second cell 21 and the metal layer Dx may be placed and routed in a grid configuration, thus, placed and routed along a grid including first grid lines G1 and second grid lines G2. In some implementations, the second cell 21 may be referred to as a second block or a second device. In some implementations, the second cell 21 may correspond to a long channel device.

For example, the second cell 21 may include an input/output device, a one-time programmable (OTP) device, an electro-static discharge (ESD) device, a passive device, an analog device, or the like. For example, the OTP device may include an OTP memory, a fuse device, an e-fuse device, or the like. For example, the ESD device may be of a diode type, a transistor type, or the like. For example, the passive device may include a resistor, a capacitor, an inductor, or the like. For example, the analog device may include a sensor, a noise removing device, a discharge device, or the like.

The first grid lines G1 may include first grid lines G11 to G16 having a first pitch P1, and the first grid lines G11 to G16 may each extend in a second direction Y. The second grid lines G2 may include second grid lines G21 to G26 having a second pitch P2, and the second grid lines G21 to G26 may each extend in a first direction X. The integrated circuit 20 may correspond to a modification of the integrated circuit 10 described with reference to FIG. 1, and the description given with reference to FIG. 1 may also be applied to the present implementations. In addition, the integrated circuit 20 may further include the first cell 11 described with reference to FIG. 1, and in this case, the first and second cells 11 and 21 and the metal layer Dx may be placed and routed along the grid including first grid lines G1 and the second grid lines G2.

The second cell 21 may include gate lines GT arranged along the first grid lines G11 to G16. In some implementations, the length of each of the gate lines GT in the first direction X may be a second length L2, and the second length L2 may be greater than the first length L1 described with reference to FIG. 1. For example, each of the gate lines GT may overlap a plurality of first grid lines. For example, the gate lines GT may include a gate line overlapping the first grid lines G11 and G12, a gate line GT2 overlapping the first grid lines G13 and G14, and a gate line overlapping the first grid lines G15 and G16. For example, the first pitch P1 may correspond to the CPP shown in FIG. 1, and the pitch of the gate lines GT may correspond to 2*CPP.

A gate contact CB may be disposed on the gate line GT2 overlapping the first grid lines G13 and G14, and the gate line GT2 may be used as a real gate line. In addition, the gate contact CB may be disposed along the second grid line G22. For example, the gate contact CB may be aligned with the second grid line G22, and a centerline of the gate contact CB may correspond to the second grid line G22.

In addition, the second cell 21 may include active patterns AP arranged along the second grid lines G2. The active patterns AP may be arranged along the second grid lines G23 to G25, and the pitch of the active patterns AP may correspond to the second pitch P2. For example, the active patterns AP may be aligned with the second grid lines G23 to G25, and centerlines of the active patterns AP may respectively correspond to the second grid lines G23 to G25. Metal lines Dx may be arranged along the second grid lines G22 to G25, and the pitch of the metal lines Dx may correspond to the second pitch P2. For example, the metal lines Dx may be respectively aligned with the second grid lines G22 to G25, and centerlines of the metal lines Dx may respectively correspond to the second grid lines G22 to G25.

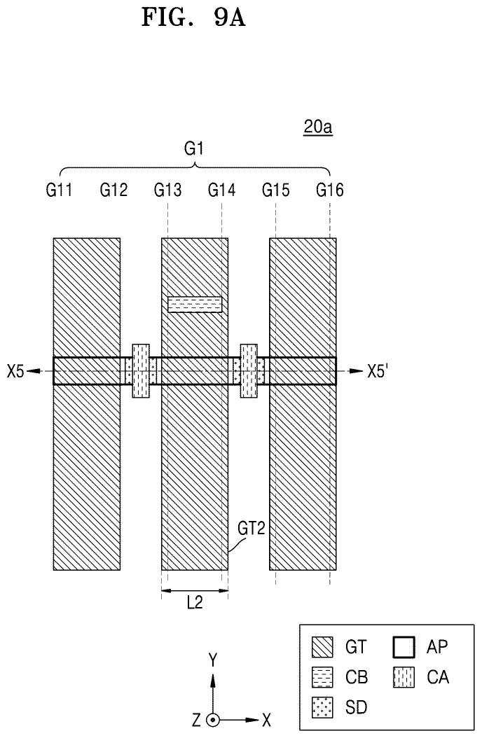

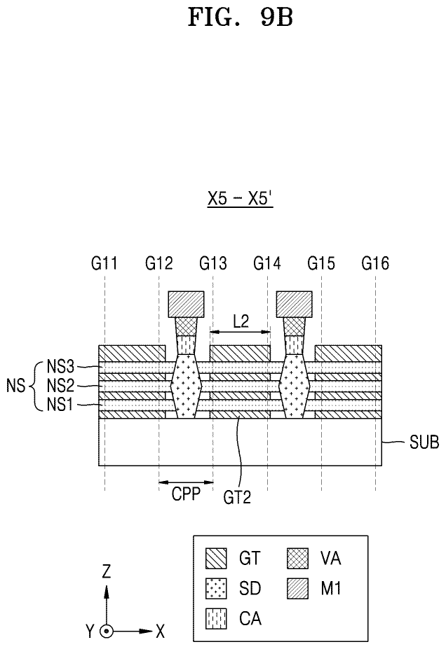

FIG. 9A is a plan view illustrating an example of an integrated circuit according to some implementations, and FIG. 9B is a cross-sectional view taken along line X5-X5′ of FIG. 9A according to some implementations. In FIGS. 9A and 9B, an integrated circuit 20a may include gate lines GT, an active pattern AP, source/drain regions SD, source/drain contacts CA, and a gate contact CB. The integrated circuit 20a may correspond to an implementation example of the integrated circuit 20 described with reference to FIG. 8, and the description given with reference to FIG. 8 may also be applied to the present implementations.

The integrated circuit 20a may further include front via layers and front metal layers that are disposed above the source/drain contacts CA and the gate contact CB. In addition, the integrated circuit 20a may further include backside via layers and backside metal layers that are disposed below the active pattern AP, the source/drain regions SD, and the gate lines GT. In some implementations, the active pattern AP may correspond to nanosheets NS, and in this case, the integrated circuit 20a may include MBCFETs.

The gate line GT2 may overlap first grid lines G13 and G14 and may extend in a second direction Y. The gate line GT2 may have a second length L2 in a first direction X. For example, the second length L2 may be greater than or equal to a first pitch P1. The gate contact CB may be disposed on the gate line GT2. The gate contact CB may be disposed between the first grid lines G13 and G14. For example, the gate contact CB may have a length corresponding to the first pitch P1 in the first direction X.

A first metal layer M1 may be disposed on the gate contact CB, and the gate line GT2 may be electrically connected to the first metal layer M1 through the gate contact CB. For example, a gate line GT overlapping first grid lines G11 and G12 and a gate line GT overlapping first grid lines G15 and G16 may correspond to dummy gate lines.

The active pattern AP may include a nanosheet stack or nanosheet NS provided above a substrate SUB and extending in the first direction X. The source/drain regions SD may be arranged on both sides of the gate line GT2. The source/drain regions SD may be electrically connected to the first metal layer M1 through the source/drain contacts CA and vias VA.

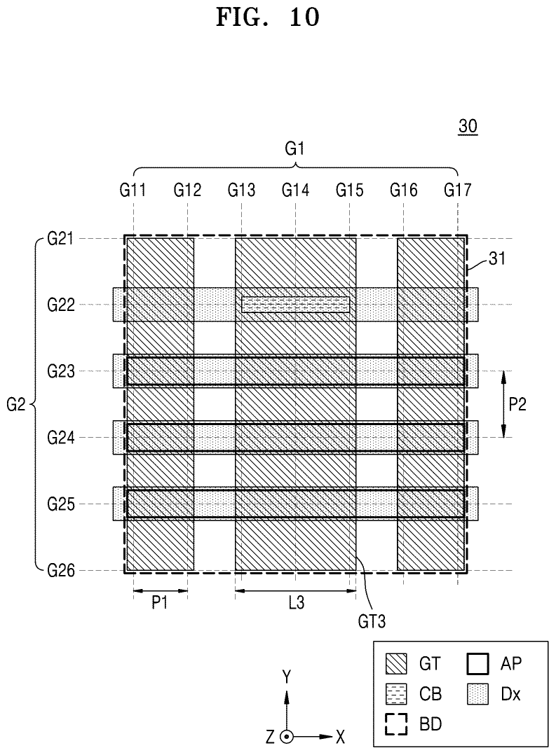

FIG. 10 is a layout illustrating an example of an integrated circuit according to some implementations. In FIG. 10, an integrated circuit 30 may include a third cell 31 and a metal layer Dx. According to some implementations, the third cell 31 and the metal layer Dx may be placed and routed in a grid configuration, thus, placed and routed along a grid including first grid lines G1 and second grid lines G2. In some implementations, the third cell 31 may be referred to as a third block or a third device. In some implementations, the third cell 31 may correspond to a long channel device. For example, the third cell 31 may include an input/output device, an OTP device, an ESD device, a passive device, an analog device, or the like.

The first grid lines G1 may include first grid lines G11 to G17 having a first pitch P1, and the first grid lines G11 to G17 may each extend in a second direction Y. The second grid lines G2 may include second grid lines G21 to G26 having a second pitch P2, and the second grid lines G21 to G26 may each extend in a first direction X. The integrated circuit 30 may correspond to a modification of the integrated circuits 10 and 20 described with reference to FIGS. 1 and 8, and the descriptions given with reference to FIGS. 1 and 8 may also be applied to some implementations. In addition, the integrated circuit 30 may further include the first cell 11 described with reference to FIG. 1 and/or the second cell 21 described with reference to FIG. 8, and in this case, the first, second and/or third cells 11, 21, and/or 31 and the metal layer Dx may be placed and routed along the grid including the first grid lines G1 and the second grid lines G2.

The third cell 31 may include gate lines GT arranged along the first grid lines G11 to G17. In an embodiment, the length of each of the gate line GT in the first direction X may be a third length L3, and the third length L3 may be greater than the first length L1 described with reference to FIG. 1 and the second length L2 described with reference to FIG. 8. In some implementations, each of the gate lines GT may overlap a plurality of first grid lines. For example, the gate lines GT may include a gate line overlapping the first grid lines G11 and G12, a gate line GT3 overlapping the first grid lines G13, G14, and G15, and a gate line overlapping the first grid lines G16 and G17.

A gate contact CB may be disposed on the gate line GT3 overlapping the first grid lines G13, G14, and G15, and the gate line GT3 may be used as a real gate line. In addition, the gate contact CB may be arranged along the second grid line G22. In addition, the gate contact CB may be aligned with the second grid line G22, and a centerline of the gate contact CB may correspond to the second grid line G22.

In addition, the third cell 31 may include active patterns AP arranged along the second grid lines G2. The active patterns AP may be arranged along the second grid lines G23 to G25, and the pitch of the active patterns AP may correspond to the second pitch P2. For example, the active patterns AP may be aligned with the second grid lines G23 to G25, and centerlines of the active patterns AP may respectively correspond to the second grid lines G23 to G25. Metal lines Dx may be arranged along the second grid lines G22 to G25, and the pitch of the metal lines Dx may correspond to the second pitch P2. For example, the metal lines Dx may be respectively aligned with the second grid lines G22 to G25, and centerlines of the metal lines Dx may respectively correspond to the second grid lines G22 to G25.

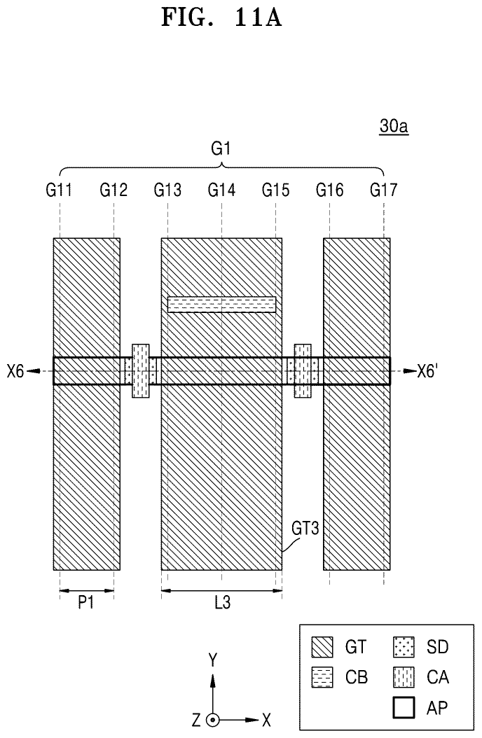

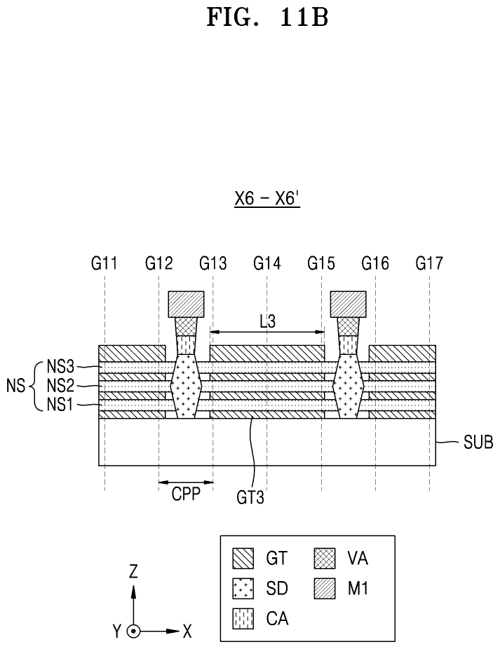

FIG. 11A is a plan view illustrating an example of an integrated circuit according to some implementations, and FIG. 11B is a cross-sectional view taken along line X6-X6′ of FIG. 11A according to some implementations. In FIGS. 11A and 11B, an integrated circuit 30a may include gate lines GT, an active pattern AP, source/drain regions SD, source/drain contacts CA, and a gate contact CB. The integrated circuit 30a may correspond to an implementation example of the integrated circuit 30 described with reference to FIG. 10, and the description given with reference to FIG. 10 may also be applied to the present implementation. The integrated circuit 30a may further include front via layers and front metal layers that are disposed above the source/drain contacts CA and the gate contact CB. In addition, the integrated circuit 30a may further include backside via layers and backside metal layers that are disposed below the active patterns AP, the source/drain regions SD, and the gate lines GT. In some implementations, the active patterns AP may correspond to nanosheets NS, and in this case, the integrated circuit 30a may include MBCFETs.

A gate line GT3 may overlap first grid lines G13, G14, and G15 and may extend in a second direction Y. The gate line GT3 may have a third length L3 in a first direction X. For example, the third length L3 may be greater than or equal to twice a first pitch P1. The gate contact CB may be disposed on the gate line GT3. The gate contact CB may be disposed between the first grid lines G13 and G15. For example, the gate contact CB may have a length corresponding to twice the first pitch P1 in the first direction X.

A first metal layer M1 may be disposed on the gate contact CB, and the gate line GT3 may be electrically connected to the first metal layer M1 through the gate contact CB. For example, a gate line GT overlapping first grid lines G11 and G12 and a gate line GT overlapping first grid lines G16 and G17 may correspond to dummy gate lines.

The active patterns AP may include a nanosheet stack or nanosheet NS provided above a substrate SUB and extending in the first direction X. The source/drain regions SD may be disposed on both sides of the gate line GT2. The source/drain regions SD may be electrically connected to the first metal layer M1 through source/drain contacts CA and vias VA.

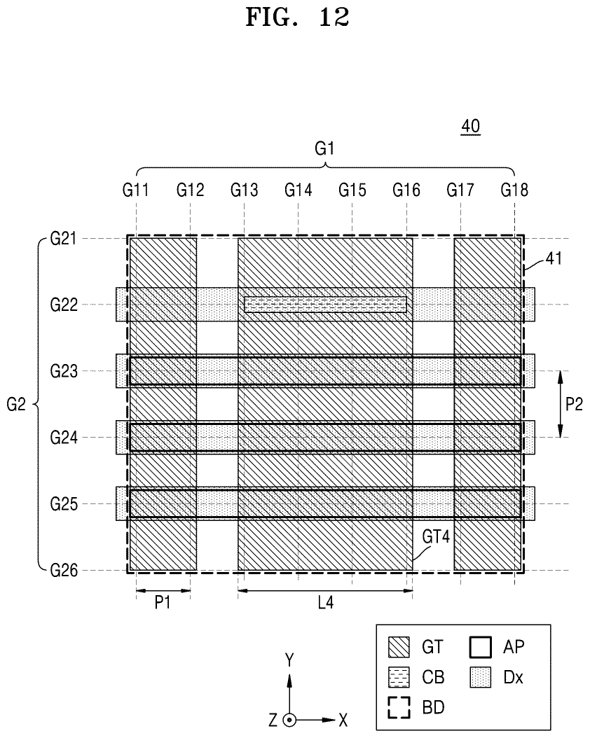

FIG. 12 is a layout illustrating an example of an integrated circuit according to some implementations. In FIG. 12, an integrated circuit 40 may include a fourth cell 41 and a metal layer Dx. According to some implementations, the fourth cell 41 and the metal layer Dx may be placed and routed in a grid configuration, thus, placed and routed along a grid including first grid lines G1 and second grid lines G2. In some implementations, the fourth cell 41 may be referred to as a fourth block or a fourth device. In some implementations, the fourth cell 41 may correspond to a long channel device. For example, the fourth cell 41 may include an input/output device, an OTP device, an ESD device, a passive device, an analog device, or the like.

The first grid lines G1 may include first grid lines G11 to G18 having a first pitch P1, and the first grid lines G11 to G18 may each extend in a second direction Y. The second grid lines G2 may include second grid lines G21 to G26 having a second pitch P2, and the second grid lines G21 to G26 may each extend in a first direction X. The integrated circuit 40 may correspond to a modification of the integrated circuits 10, 20, and 30 described with reference to FIGS. 1, 8, and 10, and the descriptions given with reference to FIGS. 1, 8, and 10 may also be applied to some implementations. In addition, the integrated circuit 40 may further include the first cell 11 described with reference to FIG. 1, the second cell 21 described with reference to FIG. 8, and/or the third cell 31 described with reference to FIG. 10. In this case, the first, second, third and/or fourth cells 11, 21, 31, and 41, and the metal layer Dx may be placed and routed along the grid including the first grid lines G1 and the second grid lines G2.

The fourth cell 41 may include gate lines GT arranged along the first grid lines G11 to G18. In an embodiment, the length of a gate line GT4 in the first direction X may be a fourth length L4, and the fourth length L4 may be greater than the first length L1 described with reference to FIG. 1, the second length L2 described with reference to FIG. 8, and the third length L3 described with reference to FIG. 10. In some implementations, each of the gate lines GT may overlap a plurality of first grid lines. For example, the gate lines GT may include a gate line overlapping the first grid lines G11 and G12, a gate line GT4 overlapping the first grid lines G13, G14, G15, and G16, and a gate line overlapping the first grid lines G17 and G18.

A gate contact CB may be disposed on the gate line GT4 overlapping the first grid lines G13, G14, G15, and G16, and the gate line GT4 may be used as a real gate line. In addition, the gate contact CB may be arranged along the second grid line G22. In addition, the gate contact CB may be aligned with the second grid line G22, and a centerline of the gate contact CB may correspond to the second grid line G22.

In addition, the fourth cell 41 may include active patterns AP arranged along the second grid lines G2. The active patterns AP may be arranged along the second grid lines G23 to G25, and the pitch of the active patterns AP may correspond to the second pitch P2. For example, the active patterns AP may be respectively aligned with the second grid lines G23 to G25, and centerlines of the active patterns AP may respectively correspond to the second grid lines G23 to G25. Metal lines Dx may be arranged along the second grid lines G22 to G25, and the pitch of the metal lines Dx may correspond to the second pitch P2. In addition, the metal lines Dx may be respectively aligned with the second grid lines G22 to G25, and centerlines of the metal lines Dx may respectively correspond to the second grid lines G22 to G25.

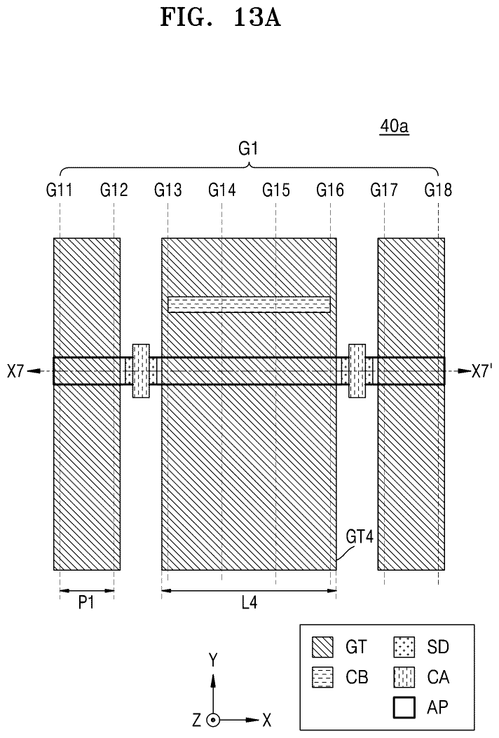

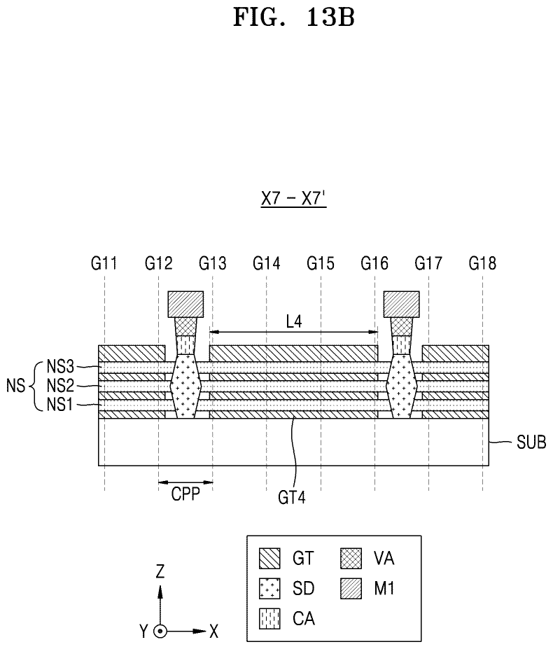

FIG. 13A is a plan view illustrating an example of an integrated circuit according to some implementations, and FIG. 13B is a cross-sectional view taken along line X7-X7′ of FIG. 13A according to some implementations. In FIGS. 13A and 13B, an integrated circuit 40a may include gate lines GT, an active patterns AP, source/drain regions SD, source/drain contacts CA, and a gate contact CB. The integrated circuit 40a may correspond to an implementation example of the integrated circuit 40 described with reference to FIG. 12, and the description given with reference to FIG. 12 may also be applied to some implementations. The integrated circuit 40a may further include front via layers and front metal layers that are disposed above the source/drain contacts CA and the gate contact CB. In addition, the integrated circuit 40a may further include backside via layers and backside metal layers that are disposed below the active patterns AP, the source/drain regions SD, and the gate lines GT. In some implementations, the active patterns AP may correspond to nanosheets NS, and in this case, the integrated circuit 40a may include MBCFETs.

A gate line GT4 may overlap first grid lines G13 to G16 and may extend in a second direction Y. The gate line GT4 may have a fourth length L4 in a first direction X. For example, the fourth length L4 may be greater than or equal to three times a first pitch P1. The gate contact CB may be disposed on the gate line GT4. The gate contact CB may be disposed between the first grid lines G13 and G16. For example, the gate contact CB may have a length corresponding to three times the first pitch P1 in the first direction X.

A first metal layer M1 may be disposed on the gate contact CB, and the gate line GT4 may be electrically connected to the first metal layer M1 through the gate contact CB. For example, a gate line GT overlapping first grid lines G11 and G12 and a gate line GT overlapping first grid lines G17 and G18 may correspond to dummy gate lines.

The active patterns AP may include a nanosheet stack or nanosheet NS provided above a substrate SUB and extending in the first direction X. The source/drain regions SD may be disposed on both sides of the gate line GT4. The source/drain regions SD may be electrically connected to the first metal layer M1 through source/drain contacts CA and vias VA.

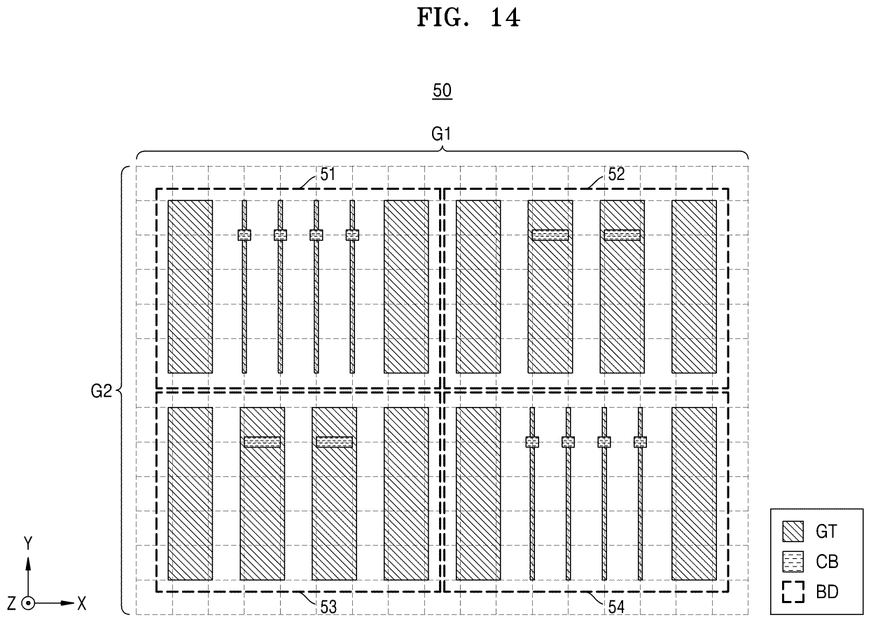

FIG. 14 is a layout illustrating an example of an integrated circuit according to some implementations. In FIG. 14, an integrated circuit 50 may include first to fourth cells 51 to 54. In this case, the first to fourth cells 51 to 54 may be arranged in a grid configuration, and arranged along a grid including first grid lines G1 and second grid lines G2. For example, the first and fourth cells 51 and 54 may correspond to short channel devices, and the second and third cells 52 and 53 may correspond to long channel devices. As described above, the integrated circuit 50 may include a block or IP including short channel devices and long channel devices. For example, the integrated circuit 50 may include an analog block, a digital block, and/or a complex signal IP.

Each of the first to fourth cells 51 to 54 may include gate lines GT arranged along the first grid lines G1, and gate contacts CB may be arranged on some of the gate lines GT. Gate lines GT connected to the gate contacts CB may be used as real gate lines, and gate lines GT not connected to the gate contacts CB may be used as dummy gate lines. For example, each of the real gate lines included in the first and fourth cells 51 and 54 may have a length in a first direction X that corresponds to the first length L1 described with reference to FIG. 1. For example, each of the real gate lines included in the second and third cells 52 and 53 may have a length in the first direction X that corresponds to the second length L2 described with reference to FIG. 8.

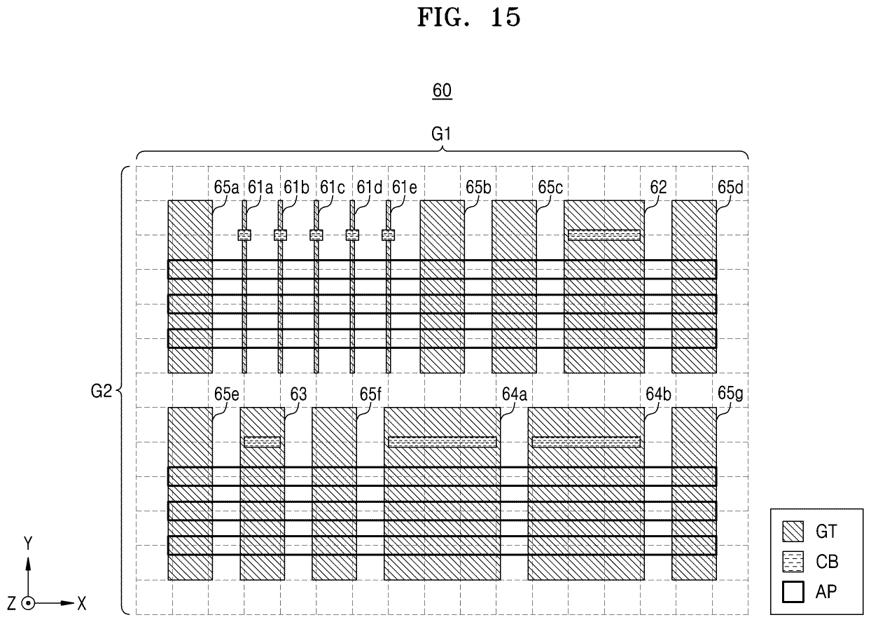

FIG. 15 is a layout illustrating an example of an integrated circuit according to some implementations. In FIG. 15, an integrated circuit 60 may include gate lines GT arranged along first grid lines G1. In some implementations, gate lines GT may have different lengths in a first direction X, and the integrated circuit 60 may include a short channel device and a long channel device. Accordingly, the integrated circuit 60 may include a block including a standard cell, digital logic, and/or an analog device, that is, a complex signal block or complex signal IP.

The gate lines GT may include gate lines 61a to 61e each overlapping one of the first grid lines G1, and the integrated circuit 60 may include a short channel device including the gate lines 61a to 61e. Gate contacts CB may be respectively disposed on the gate lines 61a to 61e, and the gate lines 61a to 61e may be used as real gate lines. The gate lines GT may further include gate lines 65a and 65b each overlapping two of the first grid lines G1. The gate lines 65a and 65b may be used as dummy gate lines, and the gate contacts CB may not be disposed on the gate lines 65a and 65b. For example, a device including the gate lines 61a to 61e, 65a, and 65b may correspond to a short channel device.

The gate lines GT may further include a gate line 62 overlapping three of the first grid lines G1. Accordingly, the integrated circuit 60 may include a long channel device including the gate line 62. A gate contact CB may be disposed on the gate line 62, and the gate line 62 may be used as a real gate line. The gate lines GT may further include gate lines 65c and 65d each overlapping two of the first grid lines G1. The gate lines 65c and 65d may be used as dummy gate lines, and the gate contact CB may not be disposed on the gate lines 65c and 65d. For example, a device including the gate lines 62, 65c, and 65d may correspond to a long channel device.

The gate lines GT may further include a gate line 63 overlapping two of the first grid lines G1. Accordingly, the integrated circuit 60 may include a long channel device including the gate line 63. A gate contact CB may be disposed on the gate line 63, and the gate line 63 may be used as a real gate line. The gate lines GT may further include gate lines 65e and 65f each overlapping two of the first grid lines G1. The gate lines 65e and 65f may be used as dummy gate lines, and the gate contact CB may not be disposed on the gate lines 65e and 65f. For example, a device including the gate lines 63, 65e, and 65f may correspond to a long channel device.

The gate lines GT may further include gate lines 64a and 64b each overlapping four of the first grid lines G1. Accordingly, the integrated circuit 60 may include a long channel device including the gate lines 64a and 64b. Gate contacts CB may be respectively disposed on the gate lines 64a and 64b, and the gate lines 64a and 64b may be used as real gate lines. The gate lines GT may further include a gate line 65g overlapping two of the first grid lines G1. The gate line 65g may be used as a dummy gate line, and the gate contact CB may not be disposed on the gate line 65g. For example, a device including the gate lines 64a, 64b, and 65g may correspond to a long channel device.

In some implementations, the gate lines 65a to 65g which are dummy gate lines may be used to distinguish different nets. Different voltages may be applied to source/drain regions provided on both sides of each of the dummy gate lines. For example, a power voltage may be applied to a source/drain region provided on a left side of a dummy gate line, and a ground voltage may be applied to a source/drain region provided on a right side of the dummy gate line.

In some implementations, the number of dummy gate lines 65a to 65g may vary. In an embodiment, one of the dummy gate lines 65b and 65c may be removed. In some implementations, when a source/drain region provided on a left side of the dummy gate line 65b and a source/drain region provided on a right side of the dummy gate line 65c are regions corresponding to the same net, all the dummy gate lines 65b and 65c may be removed. In some implementations, when a source/drain region provided on a left side of the dummy gate line 65f and a source/drain region provided on a right side of the dummy gate line 65f are regions corresponding to the same net, the dummy gate line 65f may be removed.

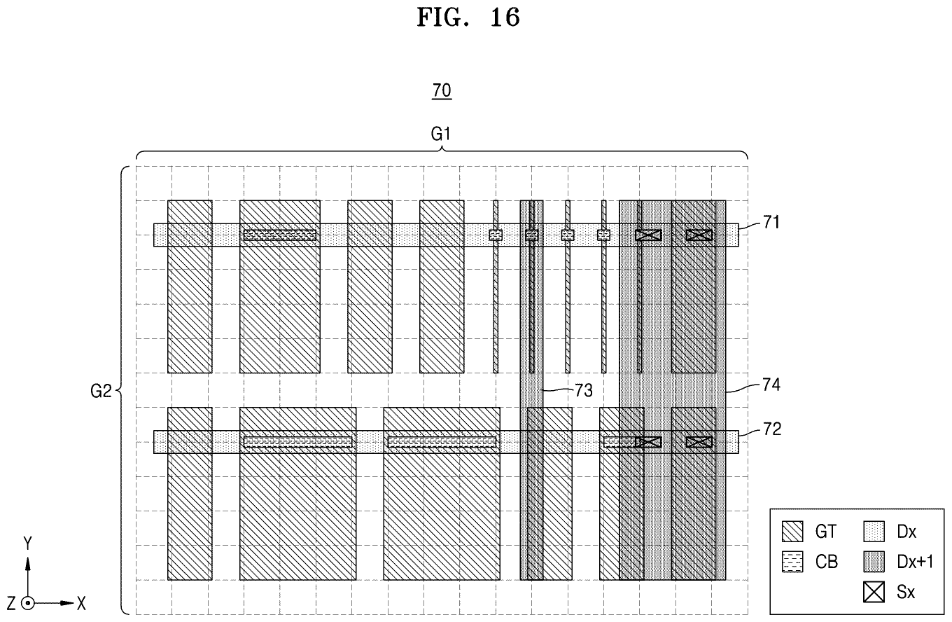

FIG. 16 is a layout illustrating an example of an integrated circuit according to some implementations. In FIG. 16, an integrated circuit 70 may include gate lines GT arranged along first grid lines G1. In some implementations, the gate lines GT may have different lengths in a first direction X, and the integrated circuit 70 may include a short channel device and a long channel device. Accordingly, the integrated circuit 70 may include a block including a standard cell, digital logic, and/or an analog device, that is, a complex signal block or a complex signal IP.

The integrated circuit 70 may further include a first upper metal layer Dx, a second upper metal layer Dx+1, and vias Sx between the first and second upper metal layers Dx and Dx+1. The first upper metal layer Dx may include first metal lines 71 and 72 routed along second grid lines G2. For example, each of the first metal lines 71 and 72 may be aligned with one of the second grid lines G2, and a centerline of each of the first metal lines 71 and 72 may correspond to one of the second grid lines G2. The second upper metal layer Dx+1 may include second metal lines 73 and 74 routed along the first grid lines G1. For example, the second metal lines 73 and 74 may be aligned with the first grid lines G1, and centerlines of the second metal lines 73 and 74 may correspond to the first grid lines G1. The second metal line 74 may be electrically connected to the first metal lines 71 and 72 through the vias Sx. For example, the vias Sx may be aligned with the second grid lines G2, and centerlines of the vias Sx may correspond to the second grid lines G2.

The integrated circuit 70 may further include active patterns, source/drain regions, and source/drain contacts. In this case, the active patterns, the source/drain regions, and the source/drain contacts may be placed and routed in a grid configuration, thus, placed and routed along a grid including the first and second grid lines G1 and G2. In addition, the integrated circuit 70 may further include front via layers and front metal layers that are disposed between the first upper metal layer Dx and the source/drain contacts or the gate contacts CB. In this case, the front via layers and the front metal layers may be placed and routed along the grid including the first and second grid lines G1 and G2. In addition, the integrated circuit 70 may further include backside contacts, backside via layers, and backside metal layers that are disposed below the active patterns, the source/drain regions, and the gate lines GT. In this case, the backside contacts, the backside via layers, and the backside metal layers may be placed and routed along the grid including the first and second grid lines G1 and G2.

As described above, the integrated circuit 70 may be designed based on the grid including the first and second grid lines G1 and G2, and patterns, lines, devices, cells, blocks, and IPs may be placed and routed along the grid including the first and second grid lines G1 and G2. Accordingly, the integrated circuit 70 may reduce unnecessary space between adjacent cells, adjacent blocks, and/or adjacent IPs, and thus, the size of a semiconductor chip including the integrated circuit 70 may be reduced.

FIGS. 17A to 17D show examples of devices according to some implementations. For example, FIG. 17A illustrates a FinFET 80a, FIG. 17B illustrates a GAAFET 80b, FIG. 17C illustrates a MBCFET 80c, and FIG. 17D illustrates a vertical field effect transistor (VFET) 80d. For case of illustration, FIGS. 17A to 17C each illustrate a state in which one of two source/drain regions is removed, and FIG. 17D illustrates a cross-section obtained by cutting the VFET 80d along a plane that is parallel to a second direction Y and a vertical direction Z and passes through a channel CH of the VFET 80d.

In FIG. 17A, the FinFET 80a may be formed by a fin-shaped active pattern extending in a first direction X between device isolation layers STI, and a gate G extending in the second direction Y. Source/drain regions S/D may be formed on both sides of the gate G, and thus, the source/drain regions S/D may be apart from each other in the first direction X. An insulating film may be formed between the channel CH and the gate G. In some implementations, the FinFET 80a may be formed by a plurality of active patterns provided apart from each other in the second direction Y, and the gate G.

In FIG. 17B, the GAAFET 80b may be formed by active patterns that are apart from each other in the vertical direction Z and extend in the first direction X, that is, nanowires; and a gate G extending in the second direction Y. Source/drain regions S/D may be formed on both sides of the gate G, and the source/drain regions S/D may be apart from each other in the first direction X. An insulating film may be formed between a channel CH and the gate G. The number of nanowires of the GAAFET 80b is not limited to that shown in FIG. 17B.

In FIG. 17C, the MBCFET 80c may be formed by: active patterns that are apart from each other in the vertical direction Z and extending in the first direction X, that is, nanosheets; and a gate G extending in the second direction Y. Source/drain regions S/D may be formed on both sides of the gate G, and thus, the source/drain regions S/D may be apart from each other in the first direction X. An insulating film may be formed between a channel CH and the gate G. The number of nanosheets of the MBCFET 80c is not limited to that shown in FIG. 17C.

In FIG. 17D, the VFET 80d may include a top source/drain region T_S/D and a bottom source/drain region B_S/D that are apart from each other in the vertical direction Z with a channel CH therebetween. The VFET 80d may include a gate G surrounding the channel CH between the top source/drain region T_S/D and the bottom source/drain region B_S/D. An insulating film may be formed between the channel CH and the gate G.

However, transistors of the present disclosure are not limited to the structures of the present implementations. For example, an integrated circuit may include a ForkFET in which nanosheets for a P-type transistor and nanosheets for an N-type transistor are separated from each other by a dielectric wall to closely dispose the P-type transistor and the N-type transistor. In addition, an integrated circuit may include a bipolar junction transistor as well as a field effect transistor (FET) such as a complementary field effect transistor (CFET), a negative capacitance field effect transistor (NCFET), or a carbon nanotube field effect transistor (CNT FET).

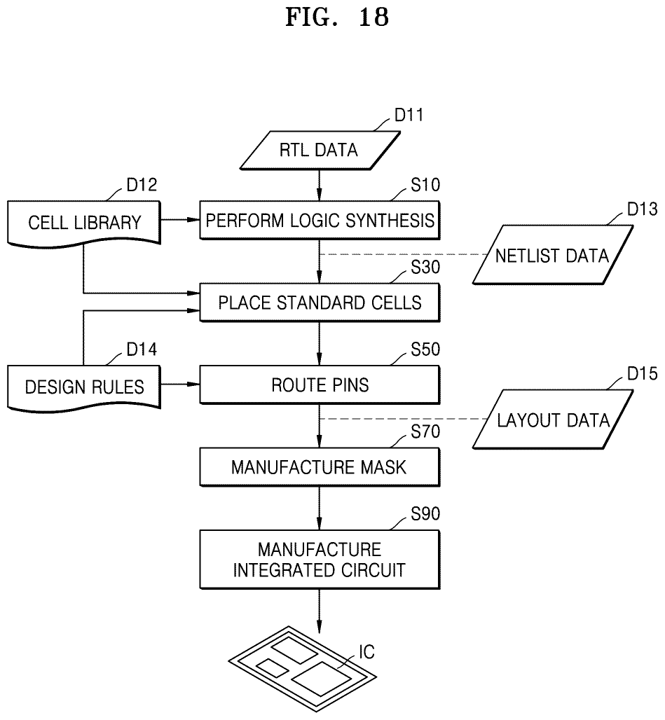

FIG. 18 is a flowchart illustrating an example of a method of manufacturing an integrated circuit according to some implementations. In FIG. 18, a method for manufacturing an integrated circuit IC that includes standard cells may include a plurality of operations S10, S30, S50, S70, and S90. A cell library (or standard cell library) D12 may include information about standard cells such as information about functions, characteristics, or layouts of standard cells. In some implementations, the cell library D12 may define tap cells and dummy cells, as well as functional cells, configured to generate output signals based on input signals. In some implementations, the cell library D12 may define memory cells and dummy cells that have the same footprint. Design rules D14 may include requirements for a layout of the integrated circuit IC. For example, the design rules D14 may include requirements for spacing between patterns in the same layer, a minimum width of patterns, routing directions of wiring layers, or the like. In some implementations, the design rules D14 may define a minimum separation distance in the same track of a wiring layer.

In operation S10, a logic synthesis operation may be performed to generate netlist data D13 from register transfer level (RTL) data D11. For example, a semiconductor design tool (such as a logic synthesis tool) may perform the logic synthesis operation using the RTL data D11 written in a hardware description language (HDL) such as very high speed integrated circuit (VHSIC) HDL (VHDL) or Verilog by referring to the cell library D12 to generate the netlist data D13 including a bitstream or netlist. The netlist data D13 may correspond to an input of place and routing (described later).

In operation S30, standard cells may be placed. According to some implementations, the standard cells may be arranged in a grid configuration, thus, arranged along a grid including first and second grid lines (for example, the first and second grid lines G1 and G2 described with reference to FIG. 1). For example, a semiconductor design tool (such as a placement and routing (P&R) tool) may place standard cells used in the netlist data D13 with reference to the cell library D12. In some implementations, before operation S30, vertical grid lines each extending in a Y-axis direction and horizontal grid lines each extending in an X-axis direction may be set in advance. In some implementations, the semiconductor design tool may place the standard cells along the horizontal grid lines and the vertical grid lines.

In operation S50, pins of the standard cells may be routed. According to some implementations, the pins may be routed along the grid including the first and second grid lines (for example, the first and second grid lines G1 and G2 described with reference to FIG. 1). For example, the semiconductor design tool may generate interconnections that electrically connect output pins and input pins of the placed standard cells to each other, and layout data D15 defining the placed standard cells and the generated interconnections. The interconnections may include vias of via layers and/or patterns of wiring layers. The wiring layers may include a front wiring layer disposed on a front upper side of a substrate and a backside wiring layer disposed on a backside side of the substrate. The layout data D15 may have a format such as graphic design system II (GDSII) and may include geometric information on the standard cells and the interconnections. The semiconductor design tool may refer to the design rules D14 while routing the pins of the standard cells. The layout data D15 may correspond to an output of place and routing. Operation S50 or operations S30 and S50 may be referred to as a method of designing an integrated circuit.

In some implementations, vias of via layers, patterns of wiring layers, through-electrodes, or the like may be routed along the horizontal grid lines and the vertical grid lines that are set in advance. For example, the pitch of the horizontal grid lines may correspond to the pitch of signal routing lines. For example, the pitch of the vertical grid lines may correspond to the minimum pitch of gate lines.

In operation S70, a mask manufacturing operation may be performed. For example, optical proximity correction (OPC), which is a technique for correcting distortion, such as refraction, caused by the characteristics of light in a photolithography process, may be applied to the layout data D15. Patterns may be defined on masks to form patterns in a plurality of layers based on data to which OPC is applied, and at least one mask (or photomask) may be manufactured to form patterns in each of the plurality of layers. In some implementations, the layout of the integrated circuit IC may be limitedly modified in operation S70. This modification of the integrated circuit IC in operation S70 may be a post-process for optimizing the structure of the integrated circuit IC and may be referred to as design polishing.

In operation S90, an operation of manufacturing the integrated circuit IC may be performed. For example, the integrated circuit IC may be manufactured by patterning the plurality of layers using the at least one mask manufactured in operation S70. A front-end-of-line (FEOL) operation may include, for example, planarizing and cleaning a wafer, forming trenches, forming wells, forming gate lines, or forming sources and drains. Individual devices, such as transistors, capacitors, resistors, or the like, may be formed on the substrate through the FEOL operation. In addition, a back-end-of-line (BEOL) operation may include, for example, siliciding gate, source, and drain regions, adding a dielectric, planarizing, forming holes, adding a metal layer, forming vias, forming a passivation layer, or the like. The individual devices, such as transistors, capacitors, resistors, or the like, may be connected to each other through the BEOL operation. In some implementations, a middle-of-line (MOL) operation may be performed between the FEOL operation and the BEOL operation, and contacts may be formed on the individual devices. The integrated circuit IC may then be packaged in a semiconductor package and used as a component in a variety of applications.

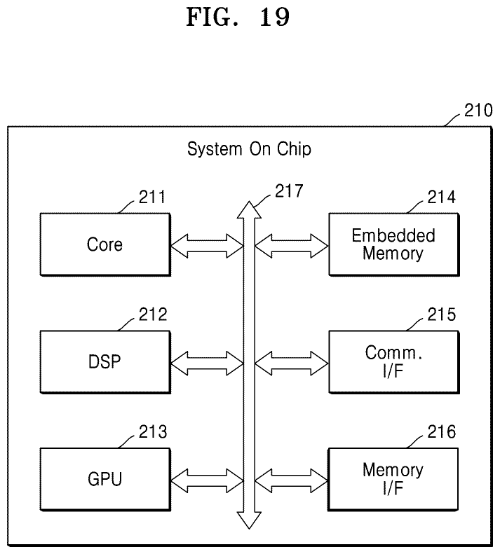

FIG. 19 is a block diagram illustrating an example of a system-on-chip (SoC) according to some implementations. In FIG. 19, a SoC 210 may refer to an integrated circuit in which components of a computing system or an electronic system are integrated. For example, an application processor (AP) that is an example of the SoC 210 may include a processor and components having other functions. The SoC 210 may include a core 211, a digital signal processor (DSP) 212, a graphics processing unit (GPU) 213, embedded memory 214, a communication interface 215, and a memory interface 216. Components of the SoC 210 may communicate with each other through a bus 217.

The core 211 may process instructions and may control operations of components included in the SoC 210. For example, the core 211 may drive an operating system and run applications on the operating system by processing a series of instructions. The DSP 212 may generate useful data by processing digital signals such as digital signals received from the communication interface 215. The GPU 213 may generate data for outputting an image through a display device from image data received from the embedded memory 214 or the memory interface 216 and may encode the image data. In some implementations, the integrated circuits described above with reference to the accompanying drawings may be included in the core 211, the DSP 212, the GPU 213, and/or the embedded memory 214.

The embedded memory 214 may store data that is necessary for operations of the core 211, the DSP 212, and GPU 213. The communication interface 215 may provide an interface for a communication network or one-to-one communication. The memory interface 216 may provide an interface for external memory of the SoC 210 such as dynamic random access memory (DRAM) or flash memory.

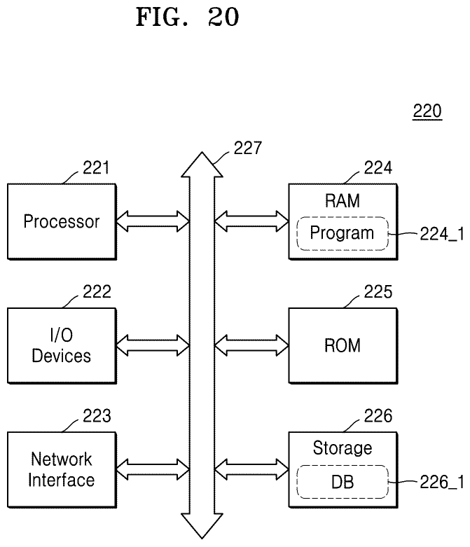

FIG. 20 is a block diagram illustrating an example of a computing system including memory storing a program according to some implementations. In FIG. 20, a computing system 220 may perform an integrated circuit designing method, for example, at least some of the operations described with reference to the flowchart shown in FIG. 18. The computing system 220 may include a processor 221, input/output devices 222, a network interface 223, random access memory (RAM) 224, read only memory (ROM) 225, and a storage 226. The processor 221, the input/output devices 222, the network interface 223, the RAM 224, the ROM 225, and the storage 226 may be connected to a bus 227 and may communicate with each other through the bus 227.

The processor 221 may be referred to as a processing unit. Like a microprocessor, an AP, a DSP, or a GPU, the processor 221 may include at least one core capable of executing an arbitrary instruction set (for example, Intel Architecture-32 (IA-32), 64-bit extended IA-32, x86-64, PowerPC, Scalable Processor Architecture (SPARC), Microprocessor without Interlocked Pipelined Stages (MIPS), Advanced RISC Machine (ARM), or IA-64). For example, the processor 221 may access memory, that is, the RAM 224 or the ROM 225, through the bus 227 and may execute instructions stored in the RAM 224 or the ROM 225.

The RAM 224 may store a program 224_1 or at least a portion of the program 224_1 for performing an integrated circuit designing method according to an embodiment, and the program 224_1 may cause the processor 221 to perform the integrated circuit designing method, for example, at least some of the operations described with reference to FIG. 18. The storage 226 may not lose data stored therein even when power supplied to the computing system 220 is cut off. According to some implementations, the storage 226 may store the program 224_1, and the program 224_1 or at least a portion of the program 224_1 may be loaded into the RAM 224. Alternatively, the storage 226 may store a file written in a program language, and the program 224_1 or at least a portion of the program 224_1 may be generated by a compiler or the like from the file and may be loaded into the RAM 224. In addition, the storage 226 may store a database 226_1, and the database 226_1 may include information necessary for designing an integrated circuit, such as information on designed blocks, the cell library D12 described with reference to FIG. 18, and/or the design rules D14 described with reference to FIG. 18.

The storage 226 may store data to be processed by the processor 221 or data processed by the processor 221. That is, the processor 221 may generate data by processing data stored in the storage 226 according to the program 224_1 and may store the generated data in the storage 226. For example, the storage 226 may store the RTL data D11, the netlist data D13, and/or the layout data D15 described with reference to FIG. 18. The input/output devices 222 may include an input device, such as a keyboard or a pointing device, and an output device, such as a display device or a printer.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. An integrated circuit comprising:
a plurality of devices arranged in a grid configuration; and
a first metal layer on the plurality of devices,
wherein the grid comprises:
a plurality of first grid lines arranged in a first direction based on a first pitch and extending in a second direction crossing the first direction; and
a plurality of second grid lines arranged in the second direction based on a second pitch and extending in the first direction,
wherein at least one of the plurality of devices comprises a plurality of gate lines extending in the second direction and having the first pitch, and
wherein the first metal layer comprises a plurality of first metal lines extending in the first direction and having the second pitch.

2. The integrated circuit of claim 1,
wherein the plurality of devices comprise:
a first cell comprising first gate lines respectively overlapping the plurality of first grid lines, each of the first gate lines extending in the second direction; and
a second cell comprising at least one second gate line overlapping the plurality of first grid lines, the at least one second gate line extending in the second direction,
wherein the first pitch corresponds to a pitch of the first gate lines, and
wherein a first length of each of the first gate lines in the first direction is less than a second length of the at least one second gate line in the first direction.

3. The integrated circuit of claim 2, wherein the second length is based on the first length and the first pitch.

4. The integrated circuit of claim 3, wherein the second length is greater than or equal to a sum of the first length and the first pitch.

5. The integrated circuit of claim 2,
wherein the first cell further comprises source/drain regions, each disposed between adjacent first grid lines among the plurality of first grid lines,
wherein a second metal layer comprising a plurality of second metal lines extend in the second direction, each of the plurality of second metal lines being electrically connected to the source/drain regions, and
wherein a pitch of the plurality of second metal lines is based on the first pitch.

6. The integrated circuit of claim 2,
wherein the second cell further comprises source/drain regions disposed on opposing sides of the at least one second gate line,
wherein a second metal layer comprising a plurality of second metal lines extending in the second direction, each of the plurality of second metal lines being electrically connected to the source/drain regions, and
wherein a pitch of the plurality of second metal lines is based on the first pitch.

7. The integrated circuit of claim 2, wherein the first cell comprises at least one of a standard cell, a static random-access memory device, or a logic device.

8. The integrated circuit of claim 2, wherein the second cell comprises at least one of an input/output device, a one-time programmable device, an electro static discharge device, a passive device, or an analog device.

9. The integrated circuit of claim 2, wherein at least one of the first cell or the second cell comprises active patterns, each active pattern extending in the first direction and respectively aligned with the plurality of second grid lines.

10. The integrated circuit of claim 1, wherein the plurality of first metal lines are respectively aligned with the plurality of second grid lines.

11. An integrated circuit comprising:
a plurality of cells arranged in a grid configuration having a first pitch,
wherein the grid comprises a plurality of grid lines arranged in a first direction based on the first pitch and extending in a second direction crossing the first direction,
wherein the plurality of cells comprise:
a first cell comprising first gate lines respectively overlapping first grid lines among the plurality of grid lines, each of the first gate lines extending in the second direction; and
a second cell comprising at least one second gate line overlapping second grid lines among the plurality of grid lines, the at least one second gate line extending in the second direction,
wherein the first pitch corresponds to a pitch of the first gate lines, and
wherein a first length of each of the first gate lines in the first direction is less than a second length of the at least one second gate line in the first direction.

12. The integrated circuit of claim 11, wherein the second length is based on the first length and the first pitch.

13. The integrated circuit of claim 11,
wherein the first cell further comprises source/drain regions, each disposed between adjacent first grid lines among the first grid lines,
wherein a metal layer comprising a plurality of metal lines extend in the second direction, each of the plurality of metal lines being electrically connected to the source/drain regions, and
wherein a pitch of the plurality of metal lines is based on the first pitch.

14. The integrated circuit of claim 11,
wherein the second cell further comprises source/drain regions disposed on opposing sides of the at least one second gate line,
wherein a metal layer comprising a plurality of metal lines extending in the second direction, each of the plurality of metal lines being electrically connected to the source/drain regions, and
wherein a pitch of the plurality of metal lines is based on the first pitch.

15. The integrated circuit of claim 11, wherein the first cell comprises at least one of a standard cell, a static random-access memory device, or a logic device.

16. The integrated circuit of claim 11, wherein the second cell comprises at least one of an input/output device, a one-time programmable device, an electro static discharge device, a passive device, or an analog device.

17. An integrated circuit comprising:
a plurality of blocks arranged in a grid configuration having a first pitch; and
a first metal layer on the plurality of blocks,
wherein the first metal layer comprises a plurality of first metal lines, each extending in a first direction and arranged apart from each other in a second direction crossing the first direction,
wherein the first pitch corresponds to a pitch of the plurality of first metal lines, and
wherein the grid comprises a plurality of grid lines extending in the first direction and arranged in the second direction based on the first pitch.

18. The integrated circuit of claim 17,
wherein the plurality of grid lines correspond to horizontal grid lines,
wherein the grid further comprises a plurality of vertical grid lines extending in the second direction and arranged in the first direction based on a second pitch,
wherein the plurality of blocks comprise:
a first block comprising first gate lines respectively overlapping first grid lines among the plurality of vertical grid lines and each extending in the second direction; and
a second block comprising at least one second gate line overlapping second grid lines among the plurality of vertical grid lines and extending in the second direction,
wherein the second pitch corresponds to a pitch of the first gate lines, and
wherein a first length of each of the first gate lines in the first direction is less than a second length of the at least one second gate line in the first direction.

19. The integrated circuit of claim 18, wherein the second length is based on the first length and the first pitch.

20. The integrated circuit of claim 18,
wherein the first block comprises at least one of a standard cell, a static random-access memory device, or a logic device, and
wherein the second block comprises at least one of an input/output device, a one-time programmable device, an electro static discharge device, a passive device, or an analog device.
